(19) United States
(12) Patent Application Publication
(10) Pub. No.: US 2012/0170286 A1
(43) Pub. Date: Jul. 5, 2012

(54) INTEGRAL LAMP ASSEMBLY AND METHOD OF CONSTRUCTION THEREOF

(76) Inventors: Jack Bodem, Kokomo, IN (US); David E. Ramey, Grand Blanc, MI (US); Johnny D. Bryant, Walling, TN (US); Jeffrey D. Simchak, Dexter, MI (US); Mark Molinaro, Leo, IN (US)

(21) Appl. No.: 13/316,898

(22) Filed: Dec. 12, 2011

Related U.S. Application Data
(60) Provisional application No. 61/421,758, filed on Dec. 10, 2010.

(51) Int. Cl. F21V 15/00; B29C 65/70; H05K 13/04

(52) U.S. Cl. 362/362; 29/887; 264/272.14

(57) ABSTRACT

An integral lamp assembly and method of construction thereof is provided. The integral lamp assembly includes a bulb and a plurality of terminals fixed to the bulb. The assembly further includes a socket having at least one through passage wherein the terminals extend through the at least one through passage. The assembly also includes a housing overmolded in bonded relation to at least one of the socket and the terminals such that the housing prevents the bulb from being removed from the socket and prevents the socket from being removed from the housing.

### CROSS-REFERENCE TO RELATED APPLICATION

This application claims the benefit of U.S. Provisional Application Ser. No. 61/421,758, filed Dec. 10, 2010, which is incorporated herein by reference in its entirety.

### BACKGROUND OF THE INVENTION

1. Technical Field

This invention relates generally to lamp assemblies, and more particularly to integral lamp assemblies having a bulb immovable therefrom and to methods of construction thereof.

2. Related Art

It is known to use miniature lamp assemblies to illuminate various portions of vehicles, such as exterior surfaces, e.g. rear deck lids, of automotive vehicles. Typically, the miniature lamp assemblies include a relatively large glass bulb installed into a relatively small socket, wherein the bulb can be readily removed from the socket for replacement. While installing the bulb into the socket, it is important to avoid damaging the bulb, which can prove challenging. A particular challenge during assembly of the bulb to the socket is to avoid applying a torsion load to the bulb that is great enough to crack or otherwise damage the bulb. If a crack or cracks go undetected, the loss of desired atmosphere inside the bulb generally reduces the useful life of the bulb. In addition, in cases where the lamp assembly is attached to a moveable surface, e.g. a rear deck lid of an automotive vehicle, it is important to avoid causing the bulb from becoming dislodged from the socket, or moved relative to the socket, such as while moving the deck lid between opened and closed positions, to avoid causing damage to the lamp assembly. Dislodging of the bulb from the socket or unwanted movement of the bulb within the socket can also be problematic when the vehicle traverses bumpy terrain.

An integral lamp assembly constructed in accordance with this invention overcomes the aforementioned problems, as well as others, which will be readily apparent to those skilled in the art of miniature lamp assemblies.

### SUMMARY OF THE INVENTION

In accordance with one aspect of the invention, an integral lamp assembly is provided. The integral lamp assembly includes a bulb and a plurality of terminals fixed to the bulb. The assembly further includes a socket having at least one through passage wherein the plurality of terminals extend through the at least one through passage. Further yet, the assembly includes a housing overmolded in bonded relation to at least one of the socket and the plurality of terminals such that the housing prevents the bulb from being removed from the socket.

In accordance with another aspect of the invention, the housing of the integral lamp assembly is overmolded in bonded relation to the socket and the plurality of terminals.

According to another aspect of the invention, a method of constructing an integral lamp assembly is provided. The method includes providing a bulb having a plurality of terminals with proximal end portions fixed to the bulb and distal end portions extending away from the bulb. The method also includes providing a socket having at least one through passage. Then, disposing the distal end portions of the plurality of terminals through the at least one through passage. Further, overmolding a housing in bonded relation to at least one of the socket and the plurality of terminals and preventing the bulb from being removable from the socket and preventing the socket from being removable from the housing.

In accordance with another aspect of the invention, the method includes overmolding the housing in bonded relation to the socket and a portion of the distal end portions of the plurality of terminals.

In accordance with another aspect of the invention, the method includes bending the plurality of terminals after inserting the distal end portions through the at least one through passage and before the overmolding the housing.

### BRIEF DESCRIPTION OF THE DRAWINGS

These and other aspects, features and advantages of the present invention will become more readily appreciated when considered in connection with the following detailed description of presently preferred embodiments and best mode, appended claims and accompanying drawings, in which:

FIG. 1 is a perspective view of an integral lamp assembly constructed in accordance with one presently preferred aspect of the invention;

FIGS. 2 is a cross-sectional view of the assembly of FIG. 1;

FIG. 3 is a perspective view of a bulb and terminal subassembly of the assembly of FIG. 1;

FIGS. 4A and 4B are bottom and top views of a socket of the assembly of FIG. 1;

FIGS. 5A and 5B are perspective and side views, respectively, of the bulb and terminal subassembly shown disposed in the socket with the terminals having been bent; and

FIGS. 6A and 6B are side and perspective views, respectively, of an overmolded housing of the assembly of FIG. 1 shown separated from the assembly of FIG. 1 for clarity of internal features otherwise non-viewable.

### DETAILED DESCRIPTION OF PRESENTLY PREFERRED EMBODIMENTS

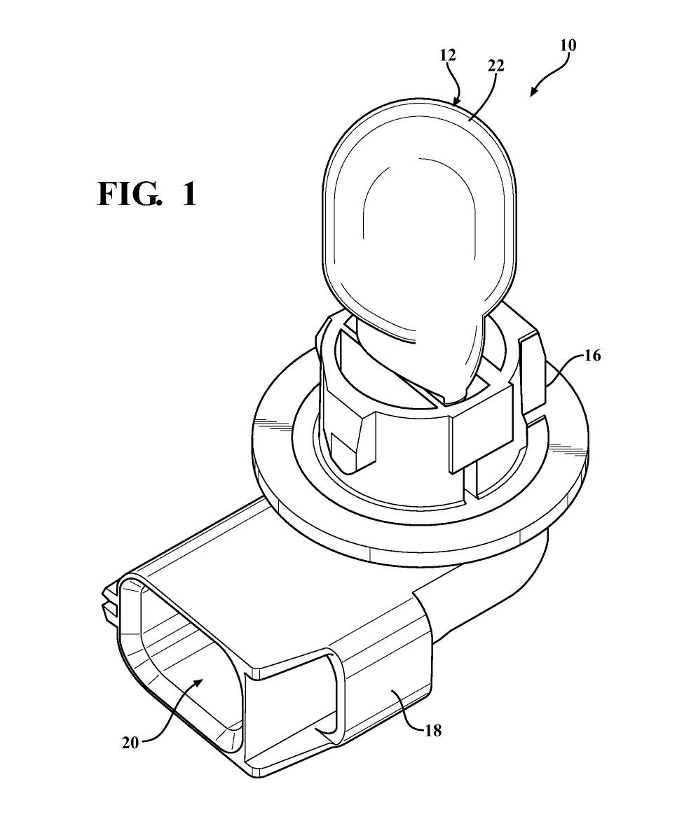

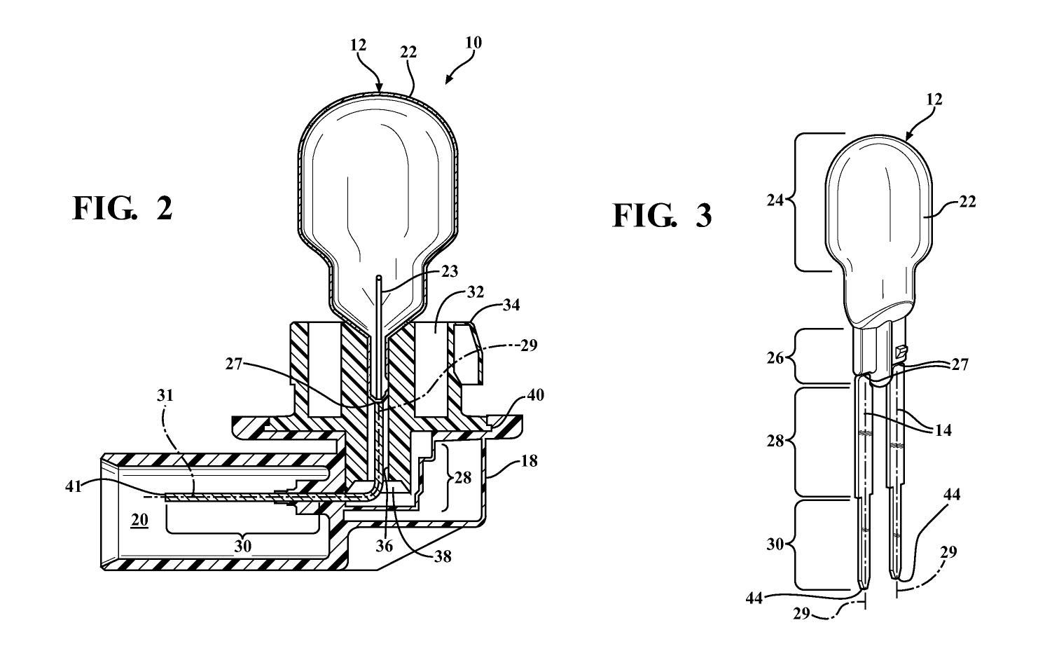

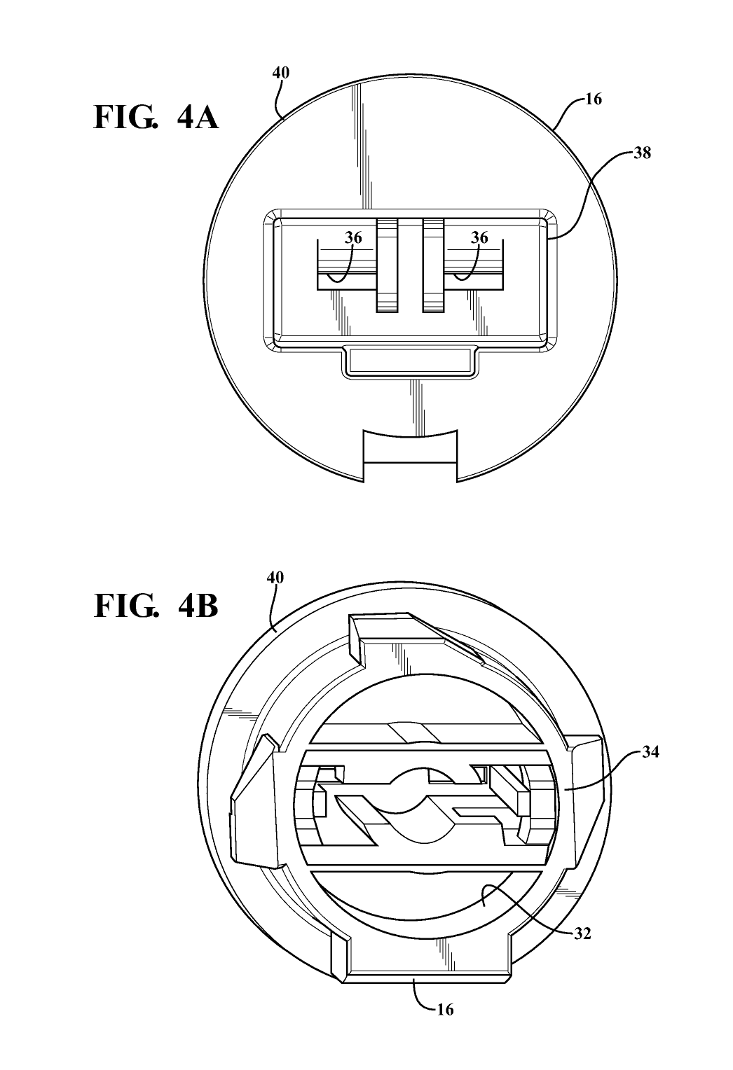

Referring in more detail to the drawings, FIGS. 1 and 2 illustrate an integral lamp assembly, referred to hereafter simply as assembly 10, constructed in accordance with one aspect of the invention. The term “integral” in intended to mean that the individual components making up the assembly 10, including a bulb 12, terminals 14, socket 16, and housing 18, are inseparable from one another without breaking at least one of the components. Accordingly, the assembly 10 is a single component, as assembled, adapted to be plugged in electrical communication with a power source via the terminals 14 in a cavity, also referred to as receptacle 20, of the housing 18. As such, upon being connected to the power source, the assembly 10 and all its assembled components are assured of remaining intact and functional in the intended application, regardless of any vibration or other types of sudden impact forces encountered. Accordingly, and in particular, the bulb 12 cannot become accidentally dislodged or otherwise manipulated and disconnected from the socket 16 upon assembly and in use. Further, while connecting the assembly 10 to the power source, the bulb 12 is unlikely to be damaged as it is unitized in fixed relation with the socket 16 and housing 18.

As best shown in FIG. 3, the bulb 12 includes an outer transparent or translucent shell 22 that houses a filament or filaments, referred to hereafter as filaments 23. The shell 22, by way of example, has an enlarge or bulbous illuminating end 24 and a reduced size terminal end 26. The filaments 23 extend into the terminal end 26 and are fixed, such as via a weld joint 27, to separate ones of the terminals 14.

The terminals 14 extend between a proximal end portion 28, which is welded to the filaments 23, and a distal end portion 30. When the proximal end portions 28 of the terminals 14 are initially fixed to the terminal end 26 of the bulb 12, and prior to being disposed through the socket 16, the terminals 14 are straight or substantially straight along their full length. Accordingly, the proximal end portions 28 and the distal end portions 30 are collinear or substantially collinear, and thus, each extends along a first axis 29. Then, upon being disposed through the socket 16, the distal end portions 30 can be bent. As such, the distal end portions 30 are formed to extend along a second axis 31, wherein the first axis 29 and the second axis 31 extend in inclined relation to one another. The bending process can be performed inside a mold cavity during the overmolding process used to form the housing 18, discussed further below.

The socket 16 is prefabricated, such as in a molding operation, from the desired polymeric material. Accordingly, the socket 16 is initially constructed as a separate component. The socket 16 has a recessed cavity, referred to hereafter as socket cavity 32, extending into an upper end 34 of the socket 16. Further, the socket 16 has at least one, and shown as a plurality of through passages 36, extending from a base or bottom surface of the cavity 32 through a lower end 38 of the socket 16. The through passages 36 are configured, i.e. sized and shaped, for close receipt of at least a portion of the terminals 14 therethrough. The socket 16 further includes a radially outwardly extending annular rim 40. The rim 40 is shown as extending radially outwardly substantially midway between the upper and lower ends 34, 38.

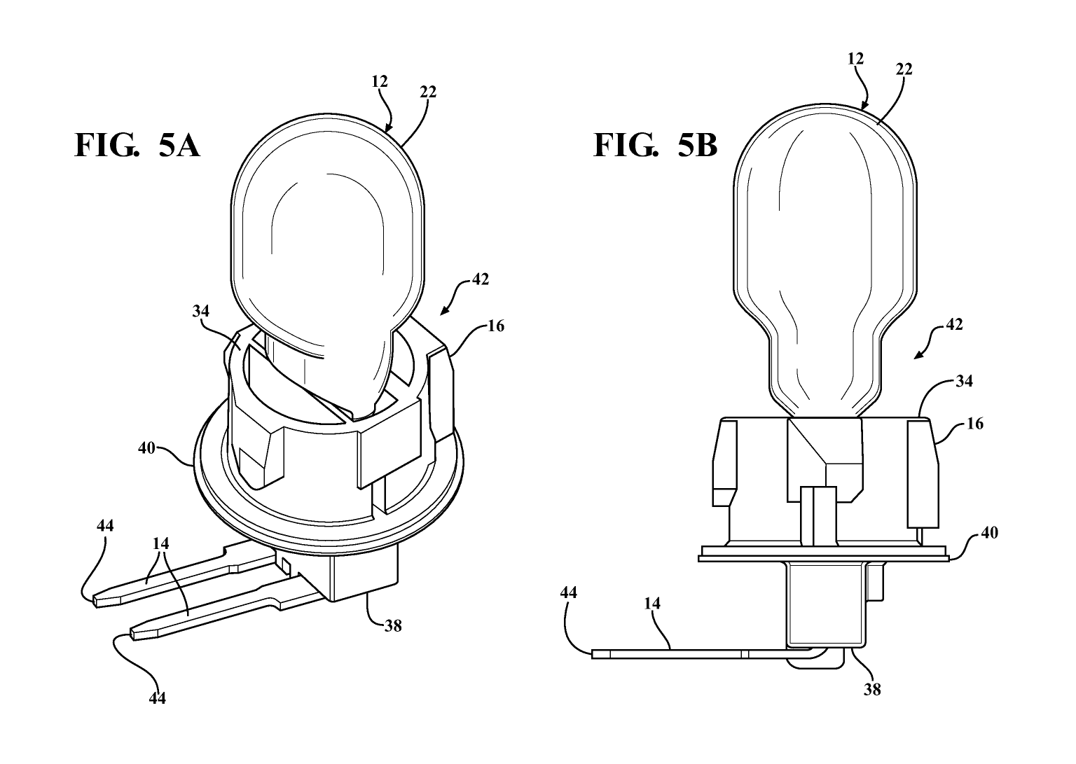

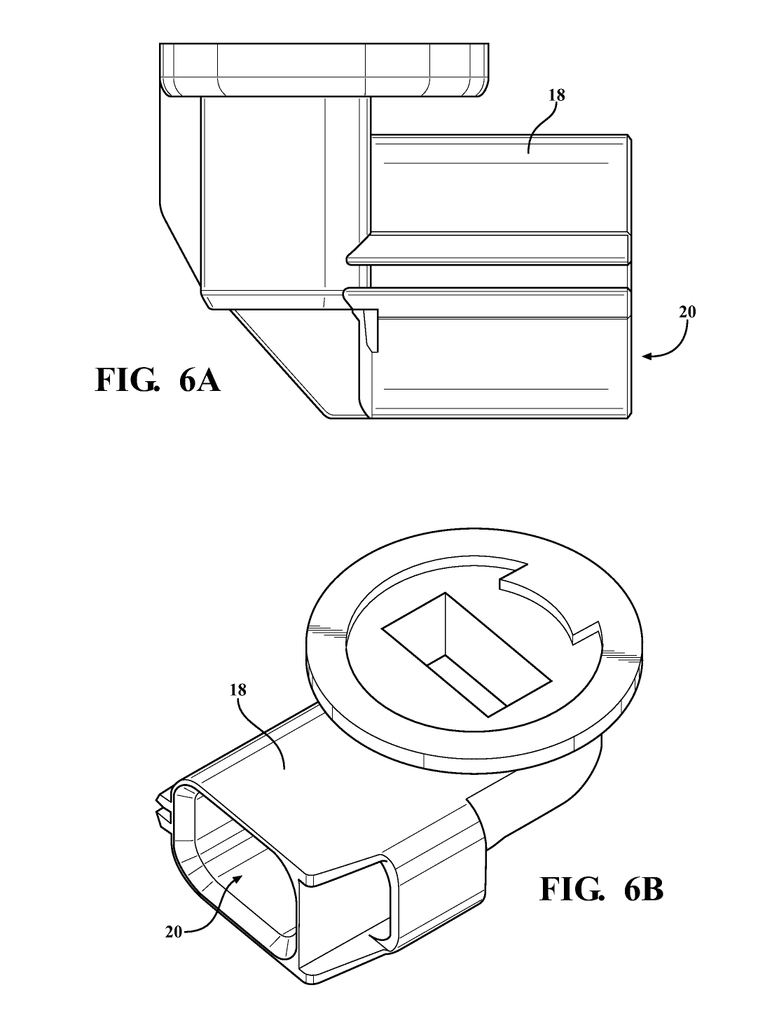

As shown, in FIGS. 5A and 5B, with the terminals 14 having been fixed to the bulb 12, the terminals 14 are disposed through the through passages 36 of the socket 16, preferably until the terminal end 26 of the bulb 12 is brought into abutment or close proximity with the base of the socket cavity 32. Then, the bulb 12 and socket 16 are disposed in a mold cavity configured to form the desired shape of the housing 18. Then, prior to overmolding the injecting the material into the mold, the distal end portions 30 are bent to incline the distal end portions 30 relative to the proximal end portions 28 by a tool in the mold cavity. In the embodiment illustrated, the distal end portions 30 and the proximal end portions 28 extend transversely or substantially transversely to one another, by way of example and without limitation, along their respective axes 29, 31. Upon bending the distal end portions 30, the distal end portions 30 are prevented from being pulled, or otherwise being inadvertently moved, outwardly from the through passages 36. Accordingly, the bulb 12 and terminals 14 are fixed and retained in the socket cavity 32, thereby forming a bulb and socket subassembly 42. It should be recognized that the terminals 14 could be bent prior to disposing the bulb 12, terminals 14 and socket 16 in the mold cavity. Accordingly, the subassembly 42 could be formed prior to insertion into the mold cavity.

Then, the polymeric material desired to form the housing 18 is injected into the mold cavity, thereby forming the housing 18 in overmolded, bonded relation about at least a portion of the socket 16. In the embodiment shown, the material of the housing 18 flows about the rim 40 of the socket 16. The housing material flows radially inwardly along the rim 40 about a lower surface of the rim 40, and can also extend along an upper surface of the rim 40 for added bonding strength, if desired. As such, at least the outer edge and lower surface of the rim 40 are bonded to the housing 18, and further the upper surface of the rim 40 can be overmolded, thereby causing the rim 40 to be fully encased and bonded to the material of the housing 18. Accordingly, the socket 16 is thoroughly fixed against removal from the housing 18. Accordingly, with the bulb 12 being fixed against removal from the socket 16 via the bent terminals 14, the bulb 12, terminals 14, socket 16 and housing 18 are integrally fixed to one another.

In addition, to further fix the bulb 12 against removal from the socket 16, the material of the housing 18 can be overmolded and bonded to a portion of the distal end portions 30. During molding of the housing 18, the receptacle 20 is formed about a portion of the distal end portions 30 and free ends 44 of the terminals 14 for receipt and attachment to the intended size electrical connector therein (not shown). It should be recognized that the receptacle 20 can be formed having any desired configuration in the overmolding process. Accordingly, portions of the distal end portions 30, including the free ends 44, are spaced from the housing 18 via the receptacle 20, and thus, are not bonded to the housing 18. Further, with the proximal end portions 28 being extending within the socket 16, the proximal end portions 28 are also not bonded to the housing 18.

Upon completing construction of the assembly 10, the individual components thereof are fixed against inadvertent movement relative to one another, thereby being protected against damage during assembly to a vehicle and also in use.

Many modifications and variations of the present invention are possible in light of the above teachings. It is, therefore, to be understood that the invention may be practiced otherwise than as specifically described, and that the scope of the invention is defined by any ultimately allowed claims.

What is claimed is:

1. An integral lamp assembly, comprising:
a bulb;
plurality of terminals fixed to said bulb;
a socket having at least one through passage, said terminals extending through said at least one through passage; and
a housing overmolded in bonded relation to at least one of said socket and said terminals, said housing preventing said bulb from being removed from said socket.

2. The integral lamp assembly of claim 1 wherein said housing is overmolded in bonded relation to said socket and said terminals.

3. The integral lamp assembly of claim 1 wherein said terminals have a proximal end portion welded to said bulb and a distal end portion, said proximal end portion extending along a first axis and said distal end portion extending along a second axis, said first axis and said second axis extending in inclined relation to one another.

4. The integral lamp assembly of claim 3 wherein said housing is overmolded in bonded relation to a portion of said distal end portion.

5. The integral lamp assembly of claim 4 wherein said housing is not bonded to said proximal end portion.

6. The integral lamp assembly of claim 4 wherein said housing is not bonded to a portion of said distal end portion.

7. The integral lamp assembly of claim 1 wherein said terminals extend from said bulb to free ends and said housing has a receptacle, said free ends being received in said receptacle.

8. A method of constructing an integral lamp assembly, comprising:
providing a bulb having a plurality of terminals with proximal end portions fixed to the bulb and distal end portions extending away from the bulb;
providing a socket having at least one through passage;
disposing the distal end portions of the plurality of terminals through the at least one through passage; and
overmolding a housing in bonded relation to at least one of the socket and the plurality of terminals and preventing the bulb from being removable from the socket.

9. The method of claim 8 wherein the overmolding step includes overmolding the housing in bonded relation to the socket and to a portion of the distal end portions of the terminals.

10. The method of claim 9 wherein the overmolding step includes avoiding overmolding the housing in bonded relation to the proximal end portions of the terminals.

11. The method of claim 8 further including bending the plurality of terminals after inserting the distal end portions through the at least one through passage and before the overmolding step.

12. The method of claim 11 wherein the overmolding step includes overmolding the housing in bonded relation to the socket and a portion of the distal end portions of the terminals.

12. The method of claim 12 wherein the overmolding step includes avoiding overmolding the housing in bonded relation to the proximal end portions.

13. The method of claim 8 further including overmolding the housing having a receptacle extending about free ends of the terminals.
